(19) United States
(12) Patent Application Publication
(10) Pub. No.: US 2008/0285354 A1
(43) Pub. Date: Nov. 20, 2008

(54) Self reference sensing system and method

(75) Inventors: Soo-Yong Park, Sunnyvale, CA (US); Takao Akaogi, Cupertino, CA (US); Michael Van Buskirk, Saratoga, CA (US)

Correspondence Address: SPANSION LLC, TECHNOLOGY LAW DEPT. M/S 68, 915 DEGUIGNE DRIVE, SUNNYVALE, CA, 94088, US

(73) Assignee: Spansion LLC

(21) Appl. No.: 11/804,170

(22) Filed: May 16, 2007

(51) Int. Cl. G11C 11/34; G11C 5/14

(52) U.S. Cl. 365/185.21; 327/53

(57) ABSTRACT

A self sensing reference system and method are described. The self sensing reference systems and methods facilitate efficient accurate access to information. In one embodiment, a self sensing reference system includes a main cascode component, a self referencing component, and a comparison verification component. The main cascode component receives input on a first current value and a second current value. The self referencing component establishes a plurality of data indications wherein a first data indication is established based upon a comparison of the first current value to the second current value. A comparison verification component verifies a second data indication.

### FIELD OF THE INVENTION

The present invention relates to the field of information sensing. In particular, the present invention relates to a self reference sensing system and method.

### BACKGROUND OF THE INVENTION

Electronic systems and circuits have made a significant contribution towards the advancement of modern society and are utilized in a number of applications to achieve advantageous results. Numerous electronic technologies such as digital computers, calculators, audio devices, video equipment, and telephone systems have facilitated increased productivity and reduced costs in analyzing and communicating data in most areas of business, science, education and entertainment. Electronic systems providing these advantageous results often include memory cells. However, accurately and efficiently accessing information stored in the memory cells can be problematic.

Memory or storage is usually a very important component of a number of systems. Memories typically store information utilized by a system in performance of a number of different tasks. Other components of a system typically request access to a memory in order to retrieve (e.g., “read”) information from or forward (e.g., “write”) information to the memory. Different types of memories (e.g., bulk storage, main memory, removable memory etc.) and or memory “spaces” (e.g., virtual, physical, etc.) can be utilized to support information storage.

Flash memory is a memory device that is being increasingly utilized in a number of applications. Flash memory devices use a memory cell transistor with a floating gate structure. The typical memory cell in a flash memory device comprises an access transistor and a storage element, such as a floating gate. Data in the flash memory device are programmed or erased by accumulation or depletion of charge. During accumulation the transistor's threshold voltage on the floating gate is raised so that the transistor does not turn on during a read cycle preventing current from flowing. During depletion the transistor's threshold voltage on the floating gate is lowered so that the transistor does turn on during a read cycle permitting current flow. The presence or lack of current flow is associated with a logical state (e.g., either a logical 0 or logical 1).

With the advent of multi-bit memory cells, the threshold voltage range to distinguish between a logical 1 and logical 0 is divided into smaller ranges. While multi-bit memory cells usually increase information storage capacity, they also typically introduce increased complexity and sensitivity in distinguishing between the threshold voltage ranges associated with logic states of the cell.

### SUMMARY

A self sensing reference system and method are described. The self sensing reference systems and methods facilitate efficient accurate access to information. In one embodiment, a self sensing reference system includes a main cascode component, a self referencing component, and a comparison verification component. The main cascode component receives input on a first current value and a second current value. The self referencing component establishes a plurality of data indications wherein a first data indication is established based upon a comparison of the first current value to the second current value. A comparison verification component verifies a second data indication.

### DESCRIPTION OF THE DRAWINGS

The accompanying drawings, which are incorporated in and form a part of this specification, illustrate embodiments of the invention by way of example and not by way of limitation. The drawings referred to in this specification should be understood as not being drawn to scale except if specifically noted.

FIG. 1A is an exemplary schematic of a multi-bit memory cell in accordance with one embodiment of the present invention.

FIG. 1B is an exemplary graph of threshold voltage distribution in accordance with one embodiment of the present invention.

FIG. 1C is a flow chart of an exemplary self reference sensing method in accordance with one embodiment of the present invention.

FIG. 1D is another flow chart of an exemplary self reference sensing method in accordance with one embodiment of the present invention.

FIG. 2A is a block diagram of an exemplary self reference sensing system in accordance with one embodiment of the present invention.

FIG. 2B block diagram of an exemplary self reference sensing system in accordance with one embodiment of the present invention.

FIG. 3A is a block diagram of an exemplary self reference sensing system in accordance with one embodiment of the present invention.

FIGS. 3B is a continuation of a block diagram of an exemplary self reference sensing system in accordance with one embodiment of the present invention.

FIG. 3C is a continuation of a block diagram of an exemplary self reference sensing system in accordance with one embodiment of the present invention.

FIG. 3D is a block diagram illustration of an exemplary implementation of sample logic in accordance with one embodiment of the present invention.

FIG. 4 is a graphical representation of an exemplary current sensing margin enhancement in accordance with one embodiment of the present invention.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

Some portions of the detailed descriptions which follow are presented in terms of procedures, logic blocks, processing, and other symbolic representations of operations on data bits within a computer memory. These descriptions and representations are the means generally used by those skilled in data processing arts to effectively convey the substance of their work to others skilled in the art. A procedure, logic block, process, etc., is here, and generally, conceived to be a self-consistent sequence of steps or instructions leading to a desired result. The steps include physical manipulations of physical quantities. Usually, though not necessarily, these quantities take the form of electrical, magnetic, optical, or quantum signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are associated with the appropriate physical quantities and are merely convenient labels applied to these quantities. Unless specifically stated otherwise as apparent from the following discussions, it is appreciated that throughout the present application, discussions utilizing terms such as “processing”, “computing”, “calculating”, “determining”, “displaying” or the like, refer to the action and processes of a computer system, or similar processing device (e.g., an electrical, optical, or quantum, computing device), that manipulates and transforms data represented as physical (e.g., electronic) quantities. The terms refer to actions and processes of the processing devices that manipulate or transform physical quantities within a computer system's component (e.g., registers, memories, other such information storage, transmission or display devices, etc.) into other data similarly represented as physical quantities within other components.

Self reference sensing methods and systems can be utilized to sense data values from a memory cell. The data values stored in a memory cell can be expressed as logical bit values (e.g., “00”. “01”, “10” and “00”). In one embodiment, the cell current difference of “00” is smaller than that of “10” and “01”. The cell currents of “11” is bigger than “0” current of “01” cell and “00” current of “00” cell. A reasonable sensing margin is valid for “00”, “01”, “10”, and “11” data storage. A sensing margin is still available even if there is an overlap between “10” and “01” (or “0”) on the voltage threshold distribution. Bit line voltage and word line voltage can be reduced facilitating power saving. The number of samples required can be as low as 1 per cell (2 bits) depending on noise effects. In addition, the dynamic references (e.g., a DREF) can be eliminated and static references (e.g., 2 SREFs) can be utilized for read operations.

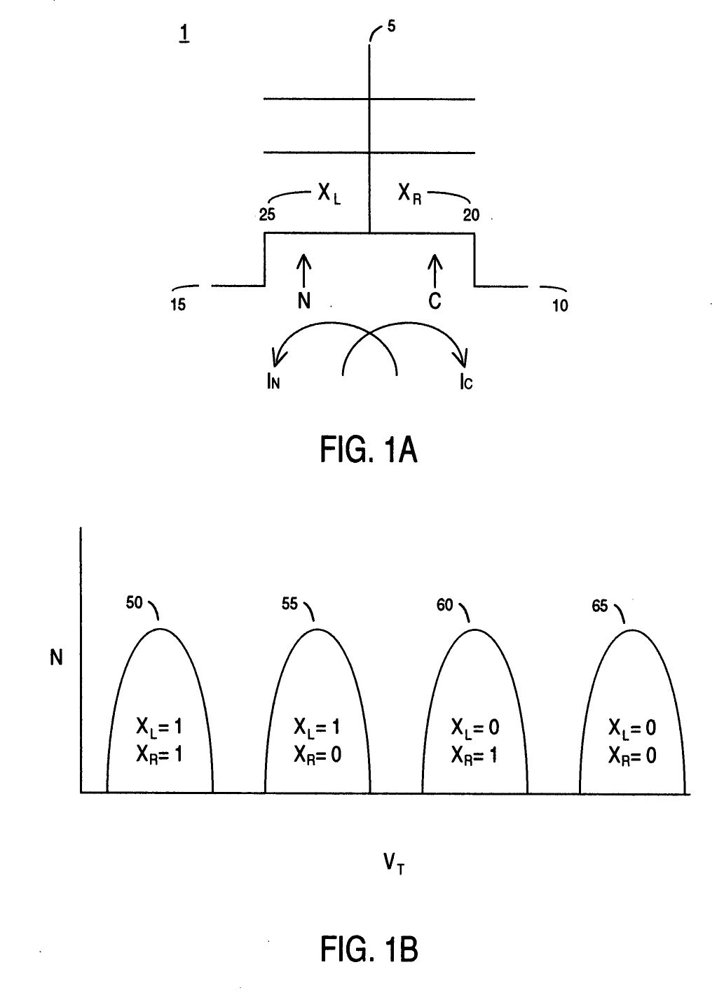

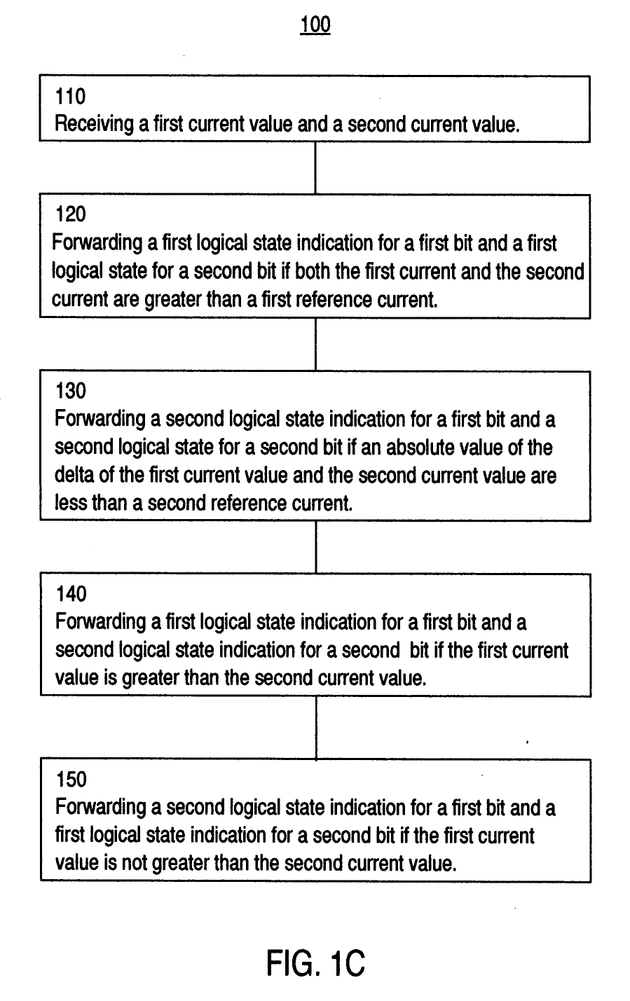

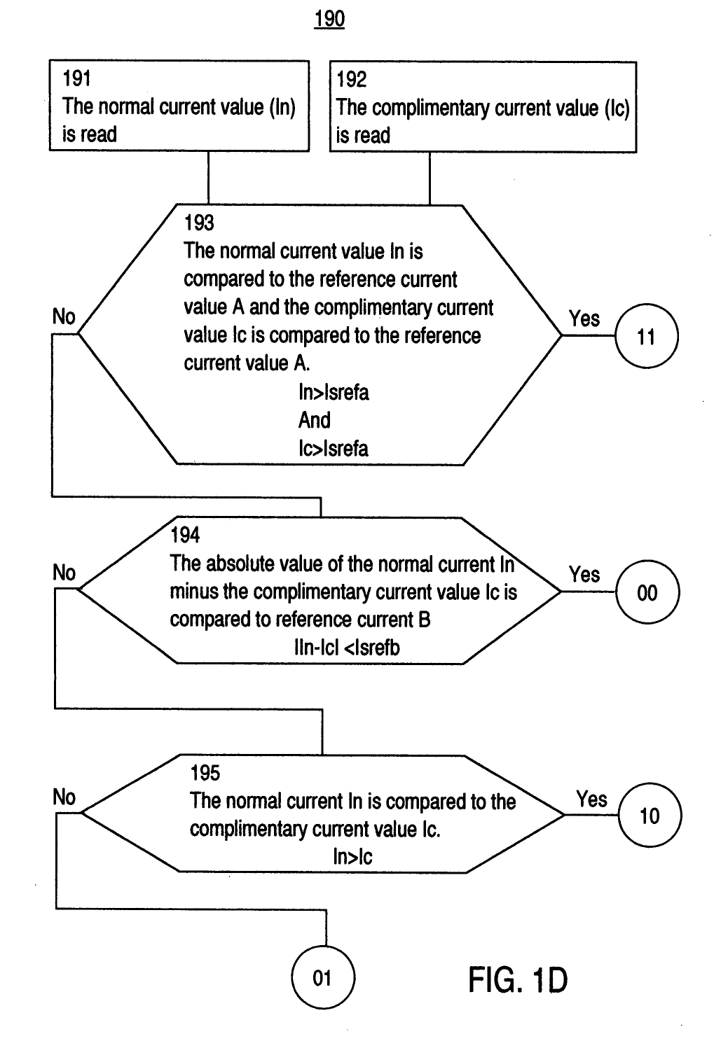

FIG. 1A is an exemplary schematic of a multi-bit memory cell 01 having a gate 5, source 15 and drain 10. The memory cell stores a left bit 25 (XL) and a right bit 20 (XR). In one embodiment, the source 15 is coupled to ground and voltages are applied to the drain 10 and gate 5 while in a sensing state. In one exemplary implementation, the left bit is associated with a normal current. In and the right bit is associate with a complimentary current Ic.

FIG. 1B is an exemplary schematic threshold voltage distribution graph in accordance with one embodiment of the present invention. Threshold voltages 50, 55, 60 and 65 are associated with logic states 11, 10, 01, and 11 respectively. The X-axis (Vt) corresponds to the threshold voltage and the Y-axis (N) represents the number of memory cells having a particular threshold voltage. In conventional multi-bit memory cell, the increased number of partitions applied to the operating voltage range usually increases problems associated distinguishing between 10 and 01 states with respect to a reference current. In one embodiment of a present self-referencing system and method the normal current and complimentary current are compared with respect to each other permitting greater flexibility and accuracy.

FIG. 1C is a flow chart of an exemplary self reference sensing method 100 in accordance with one embodiment of the present invention. Self reference sensing method 100 facilitates accurate reading data values stored in a memory cell. In one embodiment, an efficient sensing margin is valid for a variety of data values and available even if there is an overlap on the voltage threshold distribution.

At block 110 a first current value and a second current value are received. In one exemplary implementation, the first current value is associated with a first data indication (e.g., a “normal” data bit) stored in a memory cell and the second current value is associated with a second data indication (e.g., a “complimentary” data bit) stored in the memory cell.

At block 120, a first logical state indication for a first bit and a first logical state for a second bit are forwarded if both the first current and the second current are greater than a first reference current. In one embodiment, the first logic bit is a logical 1 and the second logical bit is a logical 1.

At block 130 a second logical state indication for a first bit and a second logical state for a second bit are forwarded if an absolute value of the delta of the first current value and the second current value are less than a second reference current. In one embodiment, the first logical bit is a logical 0 and the second logical bit is a logical 0.

At block 140, a first logical state indication for a first bit and a second logical state indication for a second bit are forwarded if the first current value is greater than the second current value. In one embodiment, the first logical bit is a logical 1 and the second logical bit is a logical 0. In one exemplary implementation, the first current and the second current are compared to one another.

At block 150, a second logical state indication for a first bit and a first logical state indication for a second bit are forwarded if the first current value is not greater than the second current value. In one embodiment, the first logical bit is a logical 0 and the second logical bit is a logical 1.

FIG. 1D is another flow chart of an exemplary self reference sensing method 190 in accordance with one embodiment of the present invention. In one embodiment, self reference sensing method 190 utilizes comparisons of normal current, complimentary current and reference currents to facilitate efficient reading of multi-bit data values while maintaining effective margins between values.

At block 191, the normal current value In is read. In one exemplary implementation the normal current is read through a multi-bit memory cell similar to multi-bit memory cell 01. In one embodiment, the normal current is fed into a self reference sensing system.

At block 192, the complimentary current value Ic is read. In one exemplary implementation the complimentary current is read through a multi-bit memory cell similar to multi-bit memory cell 01. In one embodiment, the complimentary current is also fed into a self reference sensing system.

At block 193, the normal current value In is compared to the reference current value A and the complimentary current value Ic is compared to the reference current value A. If the normal current value In is greater than the reference current value A and the complimentary current value Ic is greater than the reference current value A then a data value of “11” is forwarded.

At block 194 the absolute value of the normal current In minus the complimentary current value Ic is compared to reference current B. If the absolute value of the normal current In minus the complimentary current Ic is less than the reference current B a data value of “00” is forwarded.

At block 195 the normal current In is compared to the complimentary current value Ic. If the normal current In is less than the complimentary current Ic a data value of “10” is forwarded. If the normal current In is not less than the complimentary current Ic a data value of “01” is forwarded.

It is appreciated that the blocks in the flow charts are assigned numerical identifiers but that these identifiers do not necessarily indicate a sequence. For example, comparisons can be done in a parallel or serial manner.

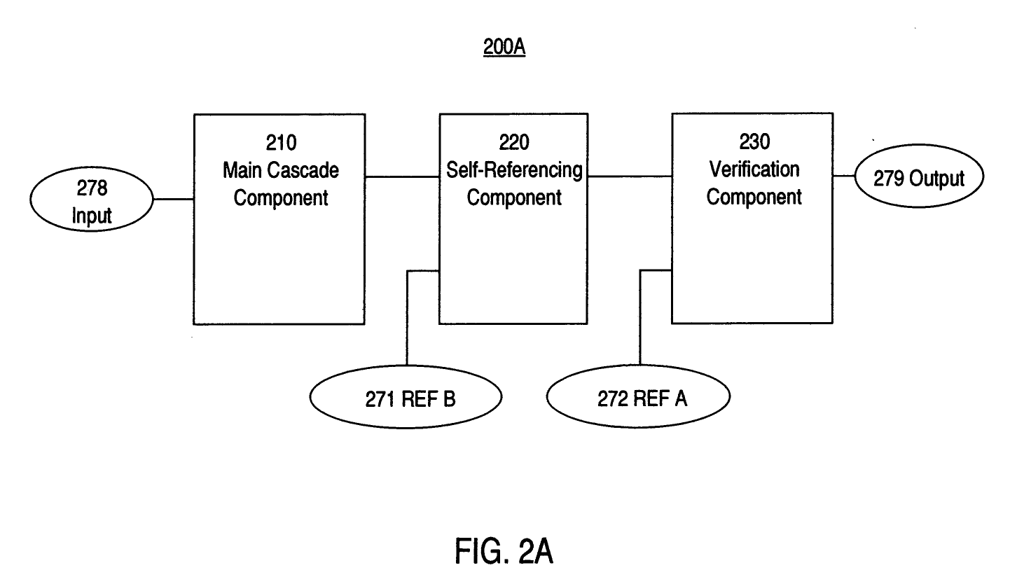

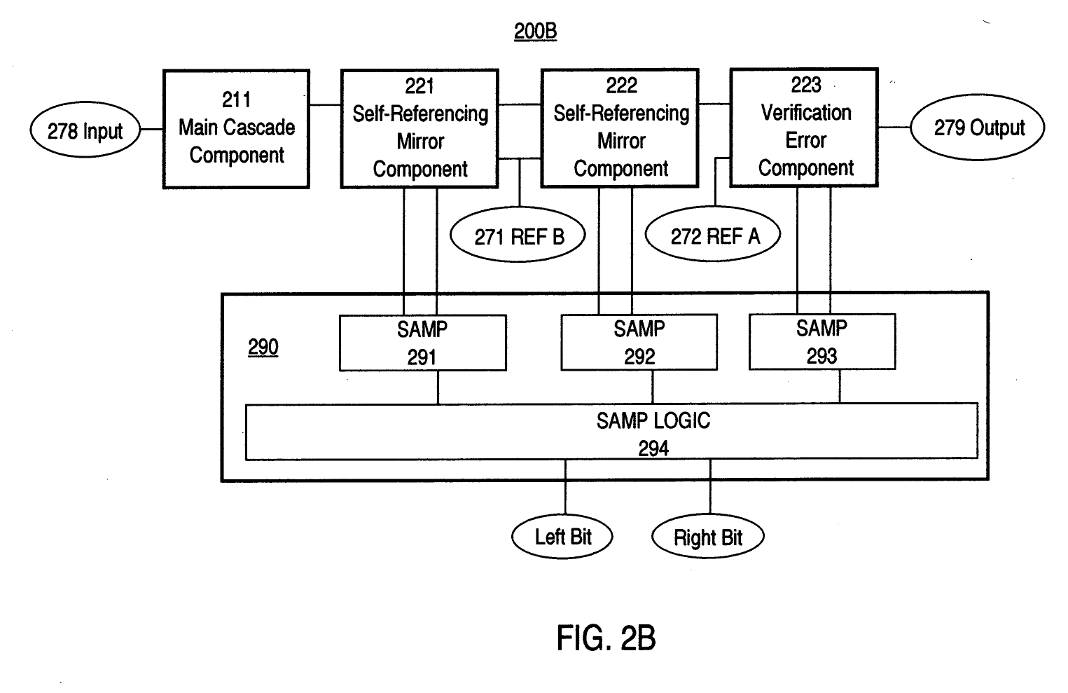

FIG. 2A is a block diagram of an exemplary self reference sensing system 200A in accordance with one embodiment of the present invention. Self reference sensing system 200A includes main cascode component 210, self referencing component 220 and comparison verification component 230. Main cascode component 210 is coupled to self referencing component 220 which in turn is coupled to comparison verification component 230.

The components of self reference sensing system 200A cooperatively operate to perform data bit sensing. Main cascode component 210 receives an input on a first current value and a second current value. Self referencing component 220 establishes a plurality of data indications wherein a first data indication is established based upon a comparison of the first current value to the second current value. The comparison verification component verifies a second data indication.

In one embodiment, self reference sensing system 200A is coupled to a memory cell and sense data indications (e.g., input signal 278) are received from the memory cell. In one exemplary implementation, the first current value is associated with a first data indication (e.g., a “normal” data bit) stored in a memory cell and the second current value is associated with a second data indication (e.g., a “complimentary” data bit) stored in the memory cell. The first data indication can include a logical 0 data bit and logical 1 data bit (e.g., 01), a logical 1 data bit and a logical 0 data bit (e.g., 10), two logical 0 data bits (e.g., 00), and/or two logical 1 data bits (e.g., 11). The first data indication can be forwarded (e.g., as output signal 279) to other components.

In one embodiment, self reference sensing system 200A utilizes a first reference value (e.g., 271 reference B) in sensing the data indications. In one exemplary implementation, the first current value is associated with a “normal” current from a memory cell and the second current value is associated with a “complimentary” current from a memory cell. The self referencing component can forward a data indication of a first logical 1 bit and a second logical 0 bit if the first current value plus a first reference value in a first cycle is greater than the second current value and the first current value is greater than the second current value plus the first reference value. The self referencing component can forward a data indication of a first logical 0 bit and a second logical 1 bit if the first current value plus a first reference value is less than the second current value and the first current value is less than the second current value plus the first reference value. The self referencing component can forward a data indication of a first logical 0 bit and a second logical 0 bit if the first current value plus a first reference value is greater than the second current value and the first current value is less than the second current value plus the first reference value. The self referencing component forwards a data indication of a first logical 1 bit and a second logical 1 bit if the first current value plus a first reference value is greater than the second current value and the first current value is less than the second current value plus the first reference value and a verification component verifies the first current value is greater than the second reference value and the second current value is greater than the second reference value.

FIG. 2B is a block diagram of an exemplary self reference sensing system 200B in accordance with one embodiment of the present invention. Self reference sensing system 200B is similar to self reference sensing system 200A. Self reference sensing system 200B includes main cascode component 211, self referencing mirror component 221, self referencing mirror component 222 verification component 231 and sample resolution component 290. Main cascode component 211 is coupled to self referencing mirror component 221 which is coupled to self referencing mirror component 222 which in turn is coupled to verification component 231. Self referencing mirror component 221, self referencing mirror component 222 and verification component 231 are coupled to sample resolution component 290.

The components of self reference sensing system 200B cooperatively operate to perform data bit sensing. Main cascode component 211 receives an input on a first current value and a second current value. Self referencing mirror component 221, self referencing mirror component 222 and verification component 231 gather sample values from multiple read cycles and coordinate forwarding of the samples to sample resolution component 290. Sample resolution component 290 performs a comparison of the sample values and forwards a data indication in accordance with the sample resolution results.

In one embodiment, sample resolution component 290 includes a first comparison component 291, a second comparison component 292, a third comparison component 293 and sample logic 294. First comparison component 291 performs a comparison of a first cycle sample and a second cycle sample from a first self referencing current mirror 221. Second comparison component 292 performs a comparison of a first cycle sample and a second cycle sample from a second self referencing current mirror 222. Third comparison component 293 performs a comparison of a first verification indication and a second verification indication from verification component 231. The sample logic component 294 forwards data indications in accordance with the results of the comparisons.

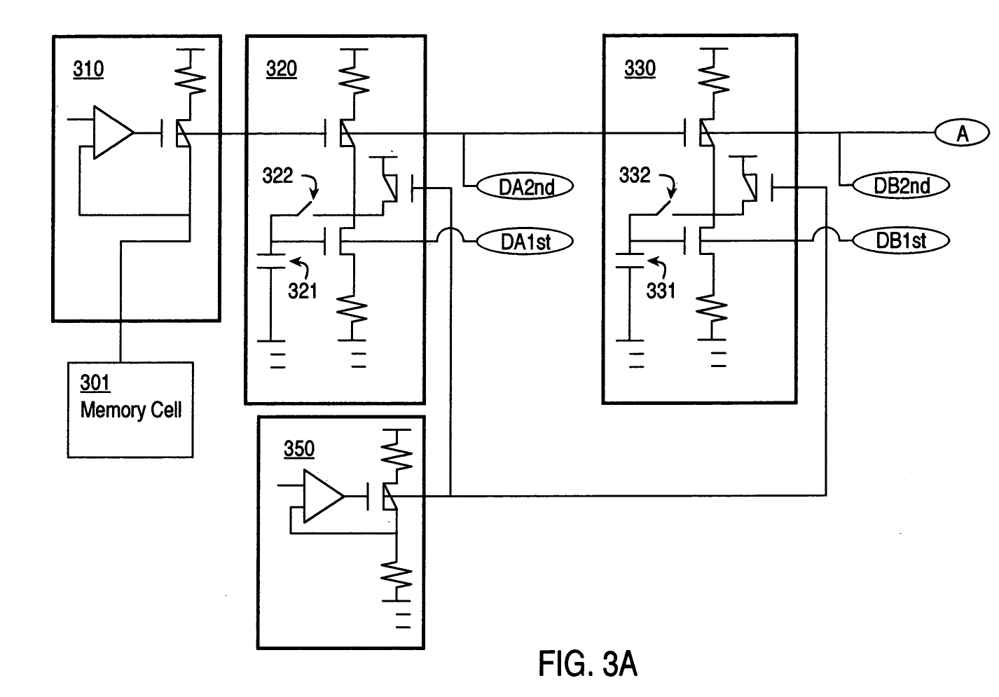

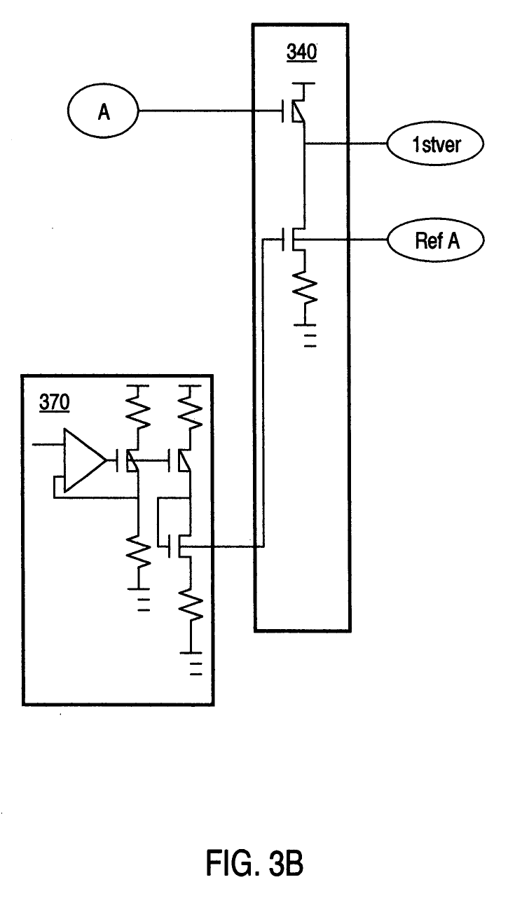

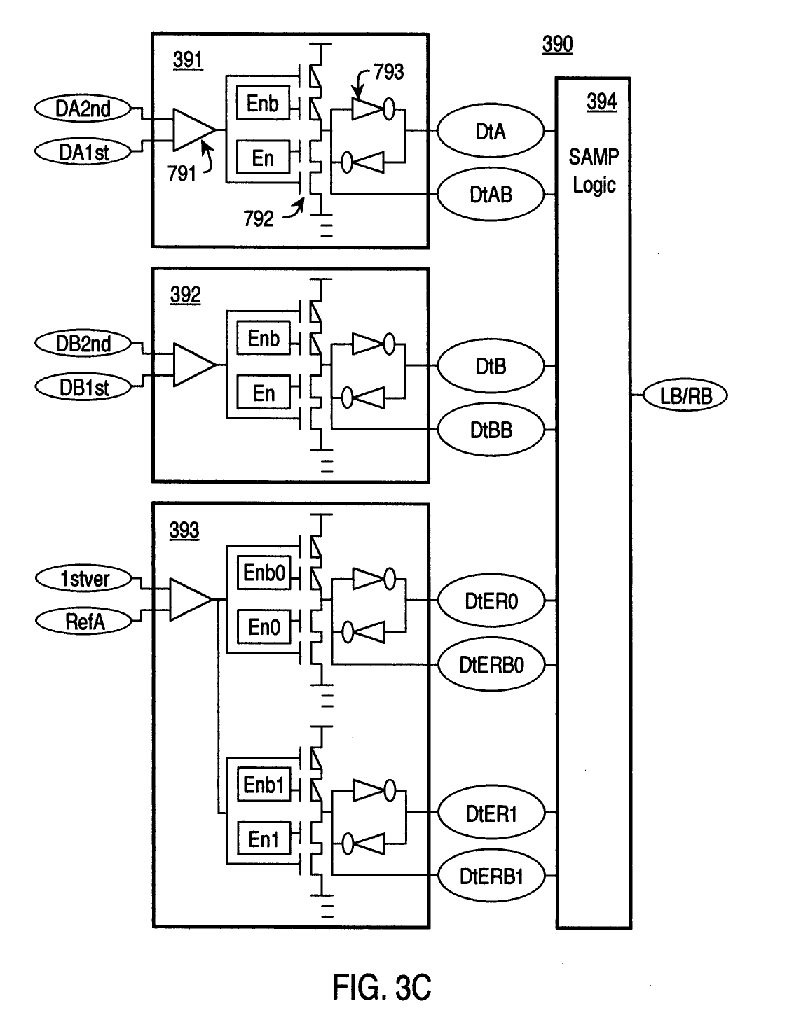

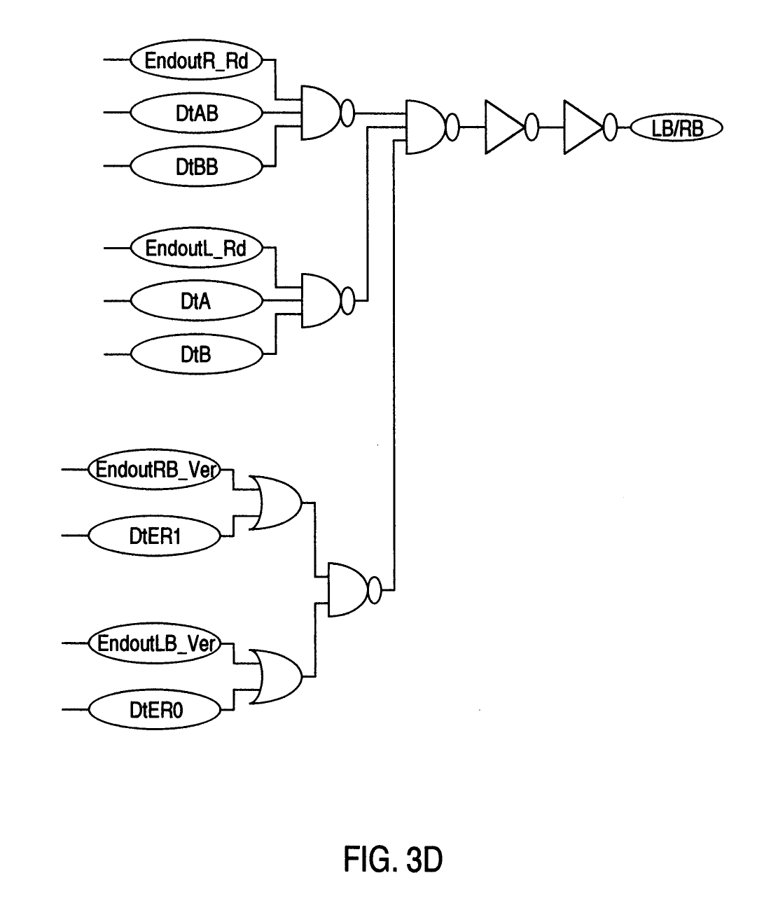

FIGS. 3A, 3B and 3C are block diagrams of an exemplary self reference sensing system 300 in accordance with one embodiment of the present invention. Self reference sensing system 300 includes main cascode component 310, a self referencing component comprising self referencing current mirror 320 and self referencing current mirror 330, verification component 340, first current reference component 350 a second current reference component 370 and sample resolution component 390.

Main cascode component 310 senses information from memory cell 310 in multiple cycles. In a first cycle main cascode component 310 forwards the normal current (e.g., In) value to current mirror 320 which adds a reference current value from reference current component 350 and the result (e.g., Ins) is stored in capacitor 321. In one exemplary implementation, switch 322 is closed during the first cycle to permit the storage in capacitor 321 and then opened during the second cycle. The normal current value is also forwarded to current mirror 330 which stores the normal current (e.g., In) value in capacitor 331. In one exemplary implementation switch 332 is closed during the first cycle to permit the storage in capacitor 311 and then opened during the second cycle. During a second cycle, main cascode component 310 forwards the complimentary current (e.g., Ic) value to current mirror 320 which forwards the complimentary current value to current mirror 330. Current mirror 330 adds the first reference current value to the complimentary current value. The normal current and complimentary current values are also sent to verification component 340. Verification component 340 also receives reference current from reference current component 370.

The current mirrors 320 and 330 and verification component 340 forward the results to sample resolution component 390. Sample resolution component 390 includes first comparison component 391, a second comparison component 392, a third comparison component 393 and sample logic 394. First comparison component 391 compares the complimentary current to the sum of the normal current and reference 350 from self referencing mirror component 320 and forwards results to sample logic 394. In one embodiment, first comparison component 391 determines if the stored value (e.g., Ins) is greater than the complimentary current value (e.g., Ic). Second comparison component 391 compares the normal current to the sum of the complimentary current and reference 350 from self referencing mirror component 330 and forwards results to sample logic 394. In one embodiment, the second comparison component 392 determines if the sum of the complimentary current and reference current (e.g., Ics) is less than the stored normal current value (e.g., In). Third comparison component 393 compares the normal current value and complimentary current values to a reference current from current reference 370. In one embodiment, comparison components (e.g., 391, 392, 393 etc.), include a differential amplifier, a control stage and a latch. In one exemplary embodiment, comparison component 391 includes a differential amplifier 791, control stage 792 including 4 transistors and a latch 793 including two inverters. The storage of information in the latches can be controlled by timing signals. The comparison components forward the results to sample logic 394.

In one embodiment, the storage of information in the latches of the comparison components (e.g., 391, 392 and 393) are controlled by timing signals associated with read cycles. In one exemplary implementation, the En and Enb enable signals of comparison components 391 and 392 are associated with a normal bit and complimentary bit cycles. For example, En is activated for normal bit read cycle and Enb is activated for the complimentary bit read cycle. The En0 and En1 of comparison component 393 are enabled for the normal bit cycle read and the Enb0 and Enb1 are enabled for the complimentary bit read cycle.

Sample logic 394 forwards data indications (e.g., the left bit LB and right bit RB indications) in accordance with the results of the comparisons. In one embodiment, sample logic 394 forwards a “00” data indication if the absolute value of In minus Ic is less than the reference current from reference current component 350. Sample logic 394 forwards a “01” data indication if In is not greater than Ic and a “10” data indication if In is greater than Ic. Sample logic 394 forwards a “11” data indication if the normal current value and complimentary current value are greater than the reference current. FIG. 3D is a block diagram illustration of an implementation of sample logic 394 in accordance with one embodiment of the present invention.

In one embodiment, the components of self reference sensing system 300 include resistors to facilitate reduction of Vt mismatches between different transistors. In one exemplary implementation, the resistors can be included on pull up and/or pull down legs of the components. For example, resistors 323, 324, 333, and 334 are utilized to facilitate reduction of Vt mismatches. In one exemplary implementations the resistors are P2sb resistors. In one embodiment, the resistors are also utilized to optimize Op amp operations.

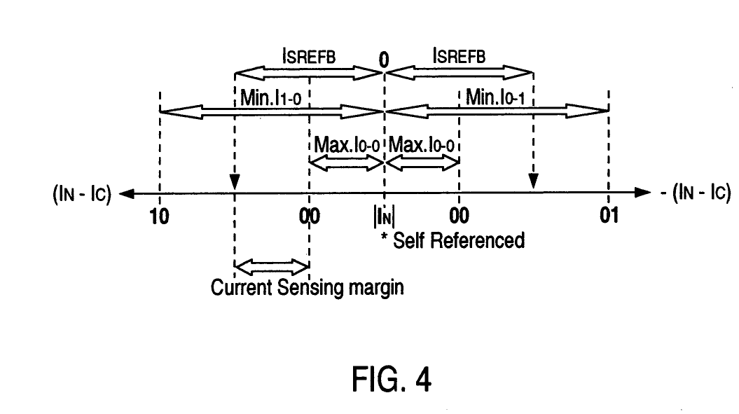

FIG. 4 is a graphical representation of an exemplary current sensing margin enhancement in accordance with one embodiment of the present invention. In one exemplary conceptual explanation, a first current reference Isrefb is added to a normal current In to produce Ins which is read. A complimentary current Ic is compared to Ins. The first current reference Isrefb is also added to the complimentary current Ic to produce Ics which is read. The normal current In and Ics are also compared. In one embodiment, the Ins is also designated as DA_{—}1^{st}, In is also designated as DB_{—}1^{st}, Ic is also designated as DA_{—}2^{nd}, and Ics is also designated as DB_{—}2^{nd}.

In one embodiment, self reference sensing system 300 operates in accordance with the following table:

| | | |
|---|---|---|
| 10 cell | DA_1^{st} > DA_2^{nd} | DB_1^{st} > DB_2^{nd} |
| 01 cell | DA_1^{st} < DA_2^{nd} | DB_1^{st} < DB_2^{nd} |
| 00 cell | DA_1^{st} > DA_2^{nd} | DB_1^{st} < DB_2^{nd} |
| 11 cell | DA_1^{st} > DA_2^{nd} | DB_1^{st} < DB_2^{nd} |

Where DA_{—}1^{st} is a sample from the first current mirror during a first cycle and DA_{—}2^{nd} is a sample from the first current mirror during a second cycle. The DB_{—}1^{st} is a sample from the second current mirror during a first cycle and DB_{—}2^{nd} is a sample from the second current mirror during a second cycle.

Thus, the present invention facilitates efficient information storage and retrieval. An effective sensing margin is valid for various data indications, including “00”. “01”, “10” and “11”. In one embodiment the sensing margin is available even if there is an overlap between “10”, “01” and/or “00” on the voltage threshold (Vt) distribution. In one exemplary implementation, power consumption can be reduced. For example, a bit line and word line voltages can be reduced. The number of sample readings can be as low as one per cell (e.g., for 2 bits).

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A self reference sensing system comprising:
a main cascode component for receiving input on a first current value and a second current value;
a self referencing component for establishing a plurality of data indications wherein a first data indication is established based upon a comparison of said first current value to said second current value; and
a comparison verification component for verifying a second data indication.

2. A self reference sensing system of claim 1 wherein said first data indication includes a first logical 0 bit and a second logical 1 bit.

3. A self reference sensing system of claim 1 wherein said first data indication includes a first logical 1 bit and a second logical 0 bit.

4. A self reference sensing system of claim 1 wherein said second data indication includes a first logical 1 bit and a second logical 1 bit.

5. A self reference sensing system of claim 1 wherein said self referencing component includes a first current mirror and a second current mirror.

6. A self reference sensing system of claim 1 wherein said self referencing component forwards a data indication of a first logical 1 bit and a second logical 0 bit if said first current value plus a first reference value in a first cycle is greater than said second current value and said first current value is greater than said second current value plus said first reference value.

7. The self reference sensing system of claim 1 wherein said self referencing component forwards a data indication of a first logical 0 bit and a second logical 1 bit if said first current value plus a first reference value is less than said second current value and said first current value is less than said second current value plus said first reference value.

8. The self reference sensing system of claim 1 wherein said self referencing component forwards a data indication of a first logical 1 bit and a second logical 1 bit if said first current value plus a first reference value is greater than said second current value and said first current value is less than said second current value plus said first reference value.

9. The self reference sensing system of claim 1 wherein said self referencing component forwards a data indication of a first logical 0 bit and a second logical 0 bit if said first current value plus a first reference value is greater than said second current value and said first current value is less than said second current value plus said first reference value and a verification component verifies said first current value is greater than said second reference value and said second current value is greater than said second reference value.

10. The self reference sensing system of claim 1 wherein said main cascode component includes a sensing component for sensing current from a memory cell.

11. A self reference sensing method comprising:
receiving a first current value and a second current value;
forwarding a first logical state indication for a first bit and a first logical state for a second bit if both said first current and said second current are greater than a first reference current;
forwarding a second logical state indication for a first bit and a second logical state for a second bit if an absolute value of the delta of said first current value and said second current value are less than a second reference current;
forwarding a first logical state indication for a first bit and a second logical state indication for a second bit if said first current value is greater than said second current value; and
forwarding a second logical state indication for a first bit and a first logical state indication for a second bit if said first current value is not greater than said second current value.

12. A self reference sensing method of claim 11 further comprising comparing said first current and said second current.

13. A self reference sensing method of claim 11 wherein said first current and said second current come from a memory cell.

14. A self reference sensing method of claim 11 wherein said first current value is associated with a normal current and said second current value is associated with a complimentary current.

15. A self reference sensing method of claim 11 wherein said first logic state indication is a logical 1.

16. A self reference sensing method of claim 11 wherein said second logic state indication is a logical 0.

17. A memory system comprising:
a memory cell for storing data; and
a self reference sensing system for sensing said data.

18. A self reference sensing method of claim 1 wherein said self reference sensing system determines a data indication value based upon a comparison of a normal current value from said memory cell and a complimentary current value from said memory cell.

19. A self reference sensing method of claim 1 wherein said memory cell includes a floating gate transistor.
